(19) United States
(12) Patent Application Publication
(10) Pub. No.: US 2024/0003519 A1
(43) Pub. Date: Jan. 4, 2024

(54) LIGHT EMITTING DEVICE, BACKLIGHT MODULE AND DISPLAY PANEL

(71) Applicant: ENPLAS CORPORATION, Kawaguchi-shi (JP)

(72) Inventor: Hiroaki OKUYAMA, Kawaguchi-shi (JP)

(73) Assignee: ENPLAS CORPORATION, Kawaguchi-shi (JP)

(21) Appl. No.: 18/364,238

(22) Filed: Aug. 2, 2023

Related U.S. Application Data
(63) Continuation of application No. 18/151,520, filed on Jan. 9, 2023.

(30) Foreign Application Priority Data
Feb. 25, 2022 (CN) 202220393100.5

(51) Int. Cl. F21V 7/00; F21V 3/00; F21V 7/24

(52) U.S. Cl. CPC F21V 7/0091; F21Y 2115/10; F21V 7/24; F21V 3/00

(57) ABSTRACT

Embodiments of the application provide a light emitting device, a backlight module and a display panel. The light emitting device comprises: a substrate; a plurality of light emitters mounted on the substrate; and a light-transmissive resin on each of the light emitters, wherein the resin is in close contact with the light emitter and a part of the substrate, a surface of the light-transmissive resin away from the light emitter and the substrate forms an exit surface, the center of the light emitter and the center of the exit surface are located in a first optical axis, a region of the exit surface near the first optical axis is recessed toward the light emitter to form a concave surface, which is configured to totally reflect part of light emitted from the center of the light emitter and transmit part of light emitted from the edge of the light emitter.

The subject patent application is a continuation of U.S. patent application Ser. No. 18/151,520, filed on Jan. 9, 2023, and entitled “LIGHT EMITTING DEVICE, BACKLIGHT MODULE AND DISPLAY PANEL,” which claims the benefit of priority to Chinese Patent Application No. 202220393100.5, filed with the Chinese Patent Office on Feb. 25, 2022, the entireties of which applications are hereby incorporated by reference herein.

### TECHNICAL FIELD

The present application relates to the field of display technology, in particular to a light emitting device, a backlight module and a display panel.

### BACKGROUND

With the development of electronic technology and the consumers' increasing requirements for display screen size and image quality, LCD has become the mainstream development trend in the industry. Wherein, the backlight module in the LCD usually comprises an edge-lit backlight module and a bottom lighting module. Compared with the edge-lit backlight module, the bottom lighting module can greatly improve the brightness and color display of the panel.

The backlight module in the related art uses a light emitting diode (LED) as a light source of the backlight module. The backlight module comprises a substrate, LEDs and a diffusion plate. A layer of light-transmissive resin is also potted on each LED to protect it. Since the LED is potted with light-transmissive resin, the divergence angle of the light emitted by the LED is small. Therefore, there may be alternating light and dark portions and uneven color on the display panel. Generally, the following two solutions can be adopted to deal with the above problems. One is to reduce the distance between adjacent LEDs, which however will lead to the need of more LEDs and is not conducive to energy saving. The other one is to increase the distance between the substrate and the diffusion plate, that is, to increase the light mixing distance (i.e., the optical distance) of light, which however will further increase the thickness of the backlight module and is not conducive to the lightweight and thinness development of the display panel.

### SUMMARY

The embodiments of the present application aim to provide a light emitting device, a backlight module and a display panel, which are conducive to increasing the divergence angle of light from light emitters, thereby increasing the spacing between adjacent light emitters, and further reducing the number of light emitters while ensuring the lightweight, thereby saving energy consumption.

In a first aspect, the present application provides a light emitting device, comprising: a substrate; a plurality of light emitters mounted on the substrate; and a light-transmissive resin on each light emitter of the light emitters, wherein the resin is in close contact with the light emitter and a part of the substrate, and a surface of the resin away from the light emitter and the substrate forms an exit surface, wherein a center of the light emitter and a center of the exit surface are located in a first optical axis, and a region of the exit surface near the first optical axis is recessed toward the light emitter to form a concave surface, which is configured to totally reflect part of light emitted from the center of the light emitter and transmit part of light emitted from an edge of the light emitter.

The light emitting device according to the embodiment of the present application improves the scattering angle of light from the light emitter by defining the shape of the light-transmissive resin on the light emitter, which is conducive to increasing the spacing between adjacent light emitters. A plurality of light emitters are mounted on the substrate, and have centers and edges when viewed from above in a direction perpendicular to the substrate. The light emitter can be in various shapes. For example, the light emitter is a cylinder, and the projection of the light emitter is circular when viewed from above; or, the light emitter is a rectangular, the projection of the light emitter is rectangular when viewed from above. A light-transmissive resin is adhered onto the substrate and the light emitter, an exit surface is formed on the surface of the resin away from the light emitter and the substrate, and a first optical axis is formed by connecting the center of the exit surface and the center of the light emitter. A portion of the exit surface near the first optical axis is recessed toward the light emitter to form a concave surface. Concave surfaces have several functions: first, when the light emitted from the center of the light emitter passes through the concave surface, part of the light is totally reflected by the concave surface onto the substrate, then reflected from the substrate, and then refracted and transmitted through the exit surface of the non-concave area, which is conducive to reducing the light intensity of the area above the center of the light emitter and improving the uniformity of the light, and further is conducive to expanding the divergence angle of the light from the center of the light emitter, thereby increasing the spacing between adjacent light emitters; second, part of the light emitted from the edge of the light emitter can also be transmitted through the concave surface, which is conducive to enhancing the light intensity of the area above the center of the light emitter, thereby improving the uniformity of the light and improving the display effect. Therefore, the provision of a concave surface on the exit surface of the light-transmissive resin is advantageous to expand the divergence angle of light from each light emitter, increase the spacing between adjacent light emitters, and further reduce the number of light emitters while ensuring the lightweight and the thinness of the light emitting device, thereby saving energy consumption.

The light emitting device according to the embodiment of the present application may further have the following additional technical features.

In some embodiments of the present application, the first optical axis is perpendicular to the substrate, and a line connecting the center of the light emitter and any point in the exit surface forms a first angle with the first optical axis; light having the first angle that is greater than 0 degree and less than or equal to 40 degrees, among the light emitted from the center of the light emitter, is totally reflected by the concave surface.

In some embodiments of the present application, the first optical axis is perpendicular to the substrate, and a line connecting the edge of the light emitter and any point in the exit surface forms a second angle with the first optical axis; light having the second angle in a range of 0 to 10 degrees, among the light emitted from the edge of the light emitter, is transmitted through the concave surface.

In some embodiments of the present application, an orthographic projection of the resin on the substrate is circular; the diameter of the orthographic projection is 8 mm to 10 mm.

In some embodiments of the present application, when the diameter of the orthographic projection is 8 mm, the height of the resin in a direction perpendicular to the substrate is 2 mm; when the diameter of the orthographic projection is 10 mm, the height of the resin in the direction perpendicular to the substrate is 2.52 mm.

In some embodiments of the present application, phosphors or light-transmissive particles are provided in the resin.

In a second aspect, the present application provides a backlight module, which comprises the light emitting device according to the first aspect and a diffusion plate arranged above the light emitting device.

The embodiments of the present application use the light emitting device according to the first aspect as a backlight source. The light-transmissive resin is provided on the light emitter in the light emitting device, a concave surface is provided on the exit surface of the resin, which is advantageous to expand the divergence angle of light from each light emitter, increase the spacing between adjacent light emitters, thereby reducing the number of light emitters while ensuring the lightweight and the thinness and thereby saving energy consumption of the backlight module.

The backlight module according to the embodiment of the present application may further have the following additional technical features:

In some embodiments of the present application, the distance between the diffusion plate and the substrate is 3 mm to 10 mm.

In some embodiments of the present application, the distance between adjacent light emitters is mm or more.

In a third aspect, the present application provides a display panel comprising the backlight module according to the second aspect.

The display panel in the embodiment of the present application comprises the backlight module according to the second aspect. The backlight module comprises the light emitting device according to the first aspect. Wherein, a light-transmissive resin is provided on the light emitter, a concave surface is provided on the exit surface of the resin, which is advantageous to expand the divergence angle of light from each light emitter, increase the spacing between adjacent light emitters, thereby reducing the number of light emitters while ensuring the lightweight and the thinness, and thereby saving energy consumption of the display panel.

It should be understood that any product or method for implementing the present application does not necessarily require all of the advantages described above.

### BRIEF DESCRIPTION OF DRAWINGS

In order to more clearly describe the technical solution of the embodiments of the present application or the prior art, drawings needed in the embodiments or the prior art will be briefly described below. Obviously, the drawings described below are for only some embodiments of the present application, other embodiments can be obtained by one of ordinary skills in the art based on the drawings illustrated herein.

FIG. 1 is a backlight module in the related art;

FIG. 2 is a top view of the light-transmissive resin of FIG. 1 on a substrate;

FIG. 3 is a structural diagram of a light emitting device according to an embodiment of the present application;

FIG. 4 is a schematic cross-sectional view taken along line D-D in FIG. 3;

FIG. 5a is a standardized waveform diagram of a backlight module in the related art;

FIG. 5b is a standardized waveform diagram in which the abscissa is enlarged in the block of FIG. 5a;

FIG. 6a is a standardized waveform diagram of one of the light emitting devices in the embodiment of the present application for lighting experiments;

FIG. 6b is a standardized waveform diagram in which the abscissa is enlarged in the block of FIG. 6a;

FIG. 7 is a structural diagram of a resin according to an embodiment of the present application;

FIG. 8 is a structural diagram illustrating the first angle and the second angle according to the embodiment of the present application;

FIG. 9a is a standardized waveform diagram of another light emitting device according to the embodiment of the present application for lighting experiments;

FIG. 9b is a standardized waveform diagram in which the abscissa is enlarged in the block of FIG. 9a;

FIG. 10 is a structural diagram of a backlight module according to an embodiment of the present application.

The reference numbers are as follows:
100′—substrate; 110—LED; 120′—diffusion plate; 100—substrate; 120—diffusion plate; 111—light-transmissive resin; H—diameter; L—height; P—light mixing distance; 10—light emitting device; 130—light emitter; 140—resin; 141—exit surface; A—the center of the light emitter; B—the center of the exit surface; C—first optical axis; 142—concave surface; 143—orthographic projection.

### DETAILED DESCRIPTION

The technical solution in the embodiments of the application will be described clearly in detail below with reference to the drawings in the embodiments of the present application. Obviously, the embodiments described herein are only some instead of all of the embodiments of the present application. All other embodiments obtained by those skilled in the art based on the embodiments in the present application fall within the protection scope of the present application.

With the development of electronic technology and the consumers' increasing requirements for display screen size and image quality, LCD has become the mainstream development trend in the industry. Wherein, the backlight module in the LCD usually comprises an edge-lit backlight module and a bottom lighting module. Compared with the edge-lit backlight module, the bottom lighting module can greatly improve the brightness and color display of the panel.

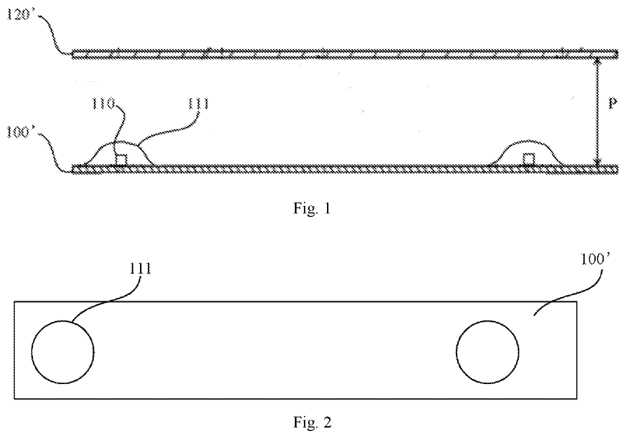

As shown in FIG. 1 and FIG. 2, a backlight module in the related art uses a light emitting diode (LED) as a light source of the backlight module. The backlight module comprises a substrate 100′, LEDs 110, a diffusion plate 120′, etc., and a layer of light-transmissive resin 111 is potted on each LED 110 to protect it. Since the LED 110 is potted with the light-transmissive resin 111, the light emitted from the LED 110 is not diffused through lenses and other components, resulting in a small light divergence angle. Therefore, in order to improve the condition of alternating light and dark portions and uneven color on the display panel, the spacing between adjacent LEDs 110 can be set small. That is, more LEDs 110 need to be used, which is not conducive to saving energy consumption; or, the distance between the substrate 100′ and the diffusion plate 120′, that is, the light mixing distance P of the light, i.e., the optical distance, can also be increased, which also can deal with the above problems. However, this will increase the thickness of the backlight module and is not conducive to the development of the lightweight display panel.

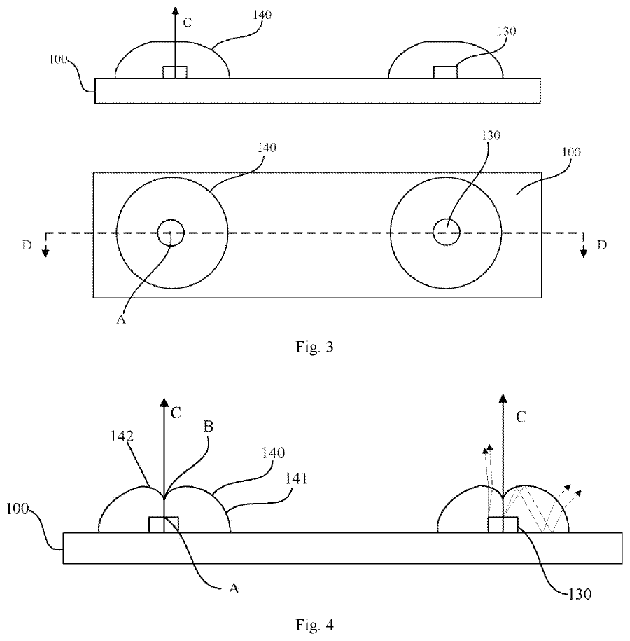

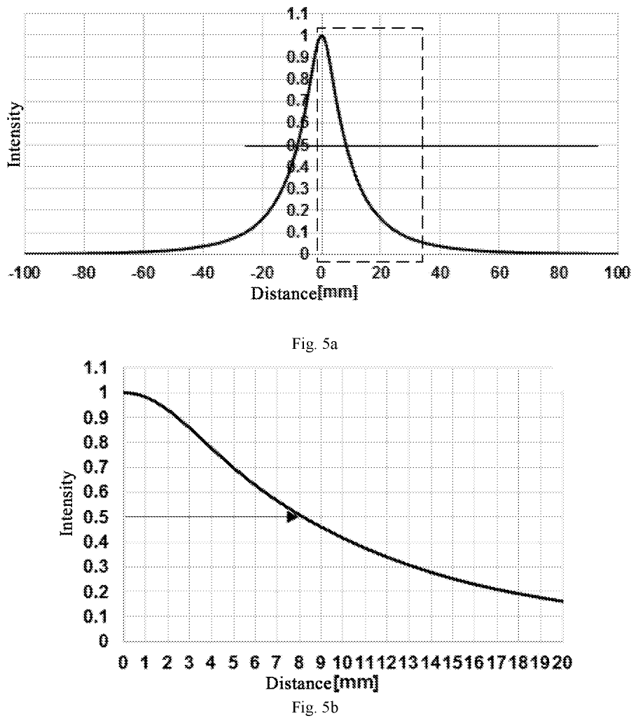

To solve the above problems, the first aspect of the present application proposes a light emitting device 10, as shown in FIG. 3 and FIG. 4. FIG. 4 is a cross-sectional view taken along the line D-D in FIG. 3. The light emitting device 10 comprises a substrate 100, a plurality of light emitters 130 mounted on the substrate 100, and a light-transmissive resin 140 on each light emitter of the light emitters 130. The resin 140 is in close contact with the light emitter 130 and a part of the substrate 100. A surface of the resin 140 away from the light emitter 130 and the substrate 100 forms an exit surface 141. The center A of the light emitter 130 and the center B of the exit surface 141 are located in the first optical axis C. A region of the exit surface 141 near the first optical axis C is recessed toward the light emitter 130 to form a concave surface 142, which is configured to totally reflect part of the light emitted from the center A of the light emitter 130 and transmit part of the light emitted from the edge of the light emitter 130.

The substrate 100 is a plate that carries the light emitter 130 and may be a PCB or the like. The plurality of light emitters 130 are mounted on the substrate 100. As shown in FIG. 3, each light emitter 130 has a center A and an edge when viewed from above in a direction perpendicular to the substrate 100. The light emitter 130 can be in various shapes. For example, the light emitter 130 is a cylinder, and the projection of the light emitter 130 is circular when viewed from above; or, the light emitter 130 is a rectangular, and the projection of the light emitter 130 is rectangular when viewed from above. The light emitter 130 may be an LED, a mini LED, or the like, which is not limited in the present application. Preferably, the light emitter 130 may be an LED emitting light from its upper surface.

A light-transmissive resin 140 is adhered to the light emitter 130, and the resin 140 may be formed of silicone, acrylic resin, polycarbonate, methyl methacrylate or styrene copolymer, or the mixture of one or two of them. The surface of the resin 140 away from the light emitter 130 and the substrate 100 is an exit surface 141, and the center B of the exit surface 141 and the center A of the light emitter 130 are connected to form a first optical axis C. A portion of the exit surface 141 near the first optical axis C is further recessed toward the light emitter 130 to form a concave surface 142.

As shown in FIG. 4, the concave surface 142 has several functions: first, when part of the light emitted from the center A of the light emitter 130 passes through the concave surface 142, the light is reflected by the concave surface 142 to the substrate 100, then reflected by the substrate 100, and then refracted and transmitted through the exit surface 141, so that it is conducive to reducing the light intensity of the area above the center A of the light emitter 130 and improving the uniformity of the light, while it is also conducive to expanding the divergence angle of the light from the center of the light emitter 130, thereby increasing the spacing between adjacent light emitters 130; second, part of the light emitted from the edge of the light emitter 130 can also be transmitted through the concave surface 142, which is conducive to enhancing the light intensity of the area above the center A of the light emitter 130, thereby improving the uniformity of the light and improving the display effect.

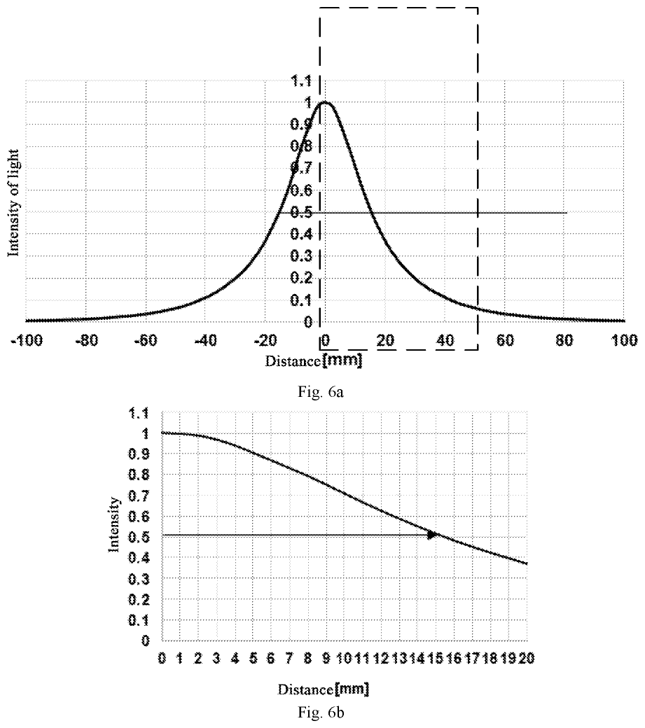

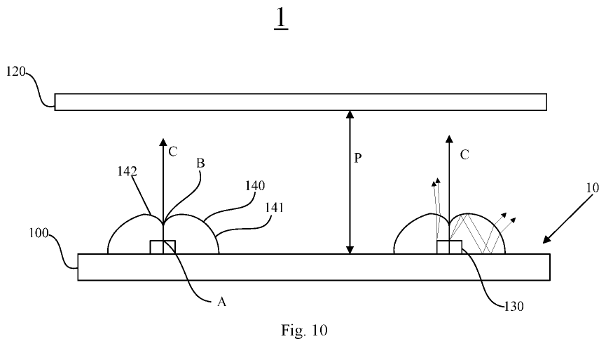

Generally, a width at half height can be used to measure the spectral line width of a luminous object, and can also be used to measure the dispersion of light intensity. The width at half height refers to the spectral width when the light intensity drops to half of the maximum light intensity. FIG. 5a and FIG. 5b show standardized waveform distribution diagrams after an experiment using the backlight module in the related art shown in FIG. 1, wherein the light mixing distance P from the substrate 100′ to the diffusion plate 120′ is 5 mm. As can be seen from FIG. 5a and FIG. 5b, the width at half height is about 16.5 mm. FIG. 6a, FIG. 6b and FIG. 10 show standardized waveform distribution diagrams of the light emitting device 10 according to the embodiment of the present application after performing a lighting experiment on the diffusion plate 120, wherein the light mixing distance P from the substrate 100 to the diffusion plate 120 is 5 mm. As can be seen from FIG. 6a and FIG. 6b, the width at half height is about 31 mm, which is about 2 times larger than the width at half height of the backlight module in the related art, so that a wider spacing arrangement between adjacent light emitters 130 can be realized, which is conducive to reducing the number of light emitters 130. That is, the light emitting device 10 according to the embodiment of the present application can improve the light distribution of the light emitter 130 and make the light from the light emitter 130 more discrete. Therefore, the provision of a concave surface 142 on the exit surface 141 of the resin 140 is advantageous to expand the divergence angle of light from each light emitter 130, increase the spacing between adjacent light emitters 130, and further reduce the number of light emitters 130 while ensuring the lightweight and the thinness of the light emitting device 10, thereby saving energy consumption.

In some embodiments of the present application, the orthographic projection 143 of the resin 140 on the substrate 100 is circular; the diameter H of the orthographic projection 143 is 8 mm to 10 mm.

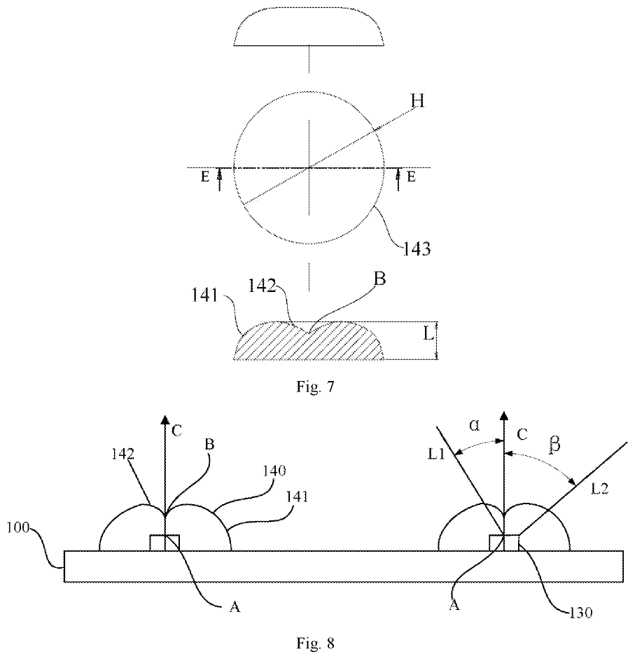

Specifically, as shown in FIG. 7, in some embodiments of the present application, the diameter H of the orthographic projection 143 of the resin 140 on the substrate 100 is 8 mm, and the height L of the resin 140 in the direction perpendicular to the substrate 100 is 2 mm. As shown in FIG. 8, the line L1 connecting the center A of the light emitter 130 and any point in the exit surface 141 forms a first angle α with the first optical axis C, and the line L2 connecting the edge of the light emitter 130 and any point in the exit surface 141 forms a second angle β with the first optical axis C.

The light having a first angle α that is greater than 0 degree and less than or equal to 40 degrees, among the light emitted from the center A of the light emitter 130, is totally reflected by the concave surface 142. In this way, the intensity of the light located above the first optical axis C can be reduced. After being reflected by the concave surface 142, the light within this angle range enters the substrate 100, reflected by the substrate 100, and refracted and transmitted through the exit surface 141, which is conducive to improving the light intensity at a position away from the first optical axis C, increasing the spacing between adjacent light emitters 130, and reducing the number of light emitters 130 to save energy. The light that coincides with the first optical axis C, that is, the light with an angle of 0 degree can be directly transmitted through the concave surface of the exit surface to supplement the light intensity of the area above the center A of the light emitter 130. The light with an angle greater than 40 degrees can be directly refracted and transmitted through the exit surface 141, which is conducive to further improving the divergence angle and uniformity of the light. The light having a second angle β in a range of 0 to 23 degrees, among the light emitted from the edge of the light emitter 130, is transmitted through the concave surface 142, which is advantageous to supplement the light intensity of the area above the center A of the light emitter 130, thereby improving the uniformity of light and improving the display effect. At this time, when the light mixing distance P is 5 mm, the width at half height of the standardized waveform is about 31 mm as shown in FIG. 6b.

In some other embodiments of the present application, the diameter H of the orthographic projection 143 is 10 mm, and the height L of the light-transmissive resin 140 in the direction perpendicular to the substrate 100 is 2.52 mm. At this time, the line L1 connecting the center A of the light emitter 130 and any point in the exit surface 141 forms a first angle α with the first optical axis C, and the line L2 connecting the edge of the light emitter 130 and any point in the exit surface 141 forms a second angle β with the first optical axis C.

The light having the first angle α that is greater than 0 degree and less than or equal to 44 degrees, among the light emitted from the center A of the light emitter 130, is totally reflected by the concave surface 142. In this way, the light intensity above the first optical axis C can be reduced. After being reflected by the concave surface 142, the light within this angle range enters the substrate 100, reflected by the substrate 100, and refracted and transmitted through the exit surface 141, which is conducive to improving the light intensity at a position away from the first optical axis C, increasing the spacing between adjacent light emitters 130, and reducing the number of light emitters 130 to save energy. The light that coincides with the first optical axis C, that is, the light with an angle of 0 degree can be directly transmitted through the concave surface of the exit surface to supplement the light intensity of the area above the center A of the light emitter 130. The light with an angle greater than 40 degrees can be directly refracted and transmitted through the exit surface 141, which is conducive to further improving the divergence angle of the light.

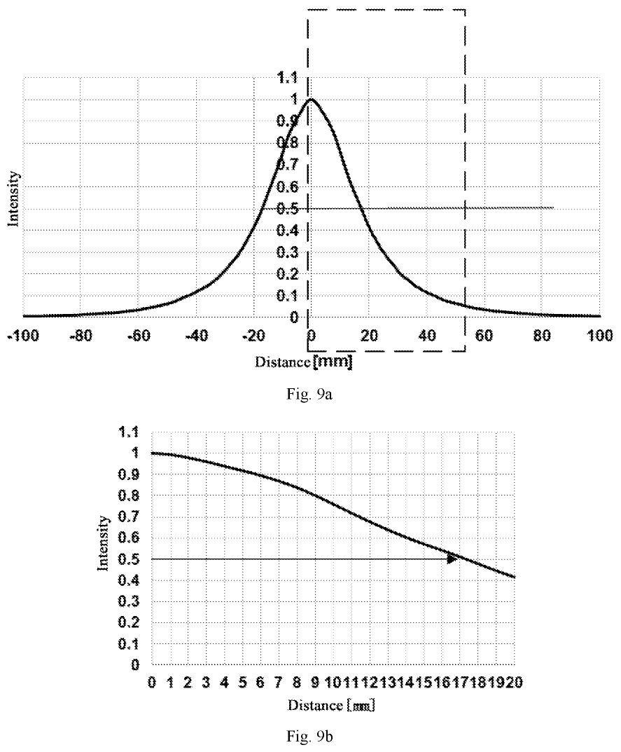

The light having a second angle β in a range of 0 to 10 degrees, among the light emitted from the edge of the light emitter 130, is transmitted through the concave surface 142, which is advantageous to supplement the light intensity of the area above the center A of the light emitter 130, thereby improving the uniformity of light and improving the display effect. From the experimental verification, the light having a second angle β in a range of 10 to 36 degrees is transmitted through the concave surface 142 to the substrate, and the light whose second angle β is larger than 36 degrees is transmitted through the concave surface 141. In this way, the scattering angle of light can be further increased. At this time, when the light mixing distance P is 5 mm, the standardized waveform is shown in FIG. 9b, whose width at half height is 34 mm.

As can be seen from the above embodiments, the concave surface 142 is provided so that the exit surface 141 of the resin 140 can be divided into a first light transmitting portion, a total reflection portion, and a second light transmitting portion.

The first light transmitting portion refers to a region of the exit surface 141 within a predetermined range centered on the first optical axis C. The first light transmitting portion may transmit first light, which is light emitted from the light emitter 130 with a small angle with respect to the first optical axis C. For example, the first light is emitted from the center A of the light emitter 130 with a first angle α of 0 degree; or, the first light is transmitted through the edge of the light emitter 130 with a second angle β in the range of 0 degree to 10 degrees.

The total reflection portion is a region in the exit surface 141 that is continuously arranged around the first light transmitting portion so as to surround the first light transmitting portion. The total reflection portion totally reflects at least the second light, which is the light emitted from the light emitter 130 with a greater angle with respect to the first optical axis C compared with the first light. For example, the second light is emitted from the center A of the light emitter 130 with a first angle α that is larger than 0 degree and less than or equal to 44 degrees; or, the second light is emitted from the edge of the light emitter 130 with a second angle β that is larger than 10 degrees and less than or equal to 36 degrees.

The second light transmitting portion is a region in the exit surface 141 that is continuously arranged around the total reflection portion so as to surround the total reflection portion. The second light transmitting portion transmits the third light, which is the light emitted from the light emitter 130 with a larger angle with respect to the first optical axis C compared with the second light. For example, the third light can be emitted from the center A of the light emitter 130 with a first angle α larger than 40 degrees. Alternatively, the third light can be emitted from the edge of the light emitter 130 with a second angle β larger than 36 degrees. Of course, the height of the light-transmissive resin 140 in the direction perpendicular to the substrate 100 can be flexibly changed. For example, when the diameter of the orthographic projection 143 is 10 mm, the height of the light-transmissive resin 140 in the direction perpendicular to the substrate 100 may also be 2.41 mm. At this time, the line L1 connecting the center A of the light emitter 130 and any point in the exit surface 141 forms a first angle α with the first optical axis C, and the line L2 connecting the edge of the light emitter 130 and any point in the exit surface 141 forms a second angle β with the first optical axis C.

The light having a first angle α that is greater than 0 degree and less than or equal to 15 degrees, among the light emitted from the center A of the light emitter 130, is totally reflected by the concave surface 142, the light in a range greater than 15 degrees is refracted and transmitted through the exit surface 141; the light emitted from the edge of the light emitter 130 can be refracted and transmitted through the concave surface 142. At this time, when the light mixing distance P is 5 mm, the width at half height of the standardized waveform is 27 mm, which is larger than 16.5 mm in the art. That is, it can also increase the spacing between adjacent light emitters 130, thereby reducing the number of light emitters 130 and saving energy consumption while ensuring lightweight and thinness.

It is understandable that when the diameter of the orthographic projection 143 is 10 mm and the height of the resin 140 in the direction perpendicular to the substrate 100 is 2.52 mm, compared with the above embodiment with the height of 2.41 mm, the spacing between adjacent light emitters 130 can be further increased (the width at half height is increased from 27 mm to 34 mm), which is conducive to further reducing the number of light emitters 130 while ensuring lightweight and the thinness and saving energy consumption.

In some embodiments of the present application, phosphors are provided in the resin 140. When activated by the light from the light emitter 130, the phosphors can emit light of other colors, which can also be mixed with the light from the light emitter 130 to obtain white light, so as to fulfill the need for white backlight.

In some other embodiments of the present application, light-transmissive particles may also be provided in the resin 140. For example, silicone particles, silica particles, melamine formaldehyde condensation particles, or the like may be added, which is conducive to improving the light transmittance of the resin 140 and further reducing the light intensity loss.

As shown in FIG. 10, the second aspect of the present application provides a backlight module 1, which comprises the light emitting device 10 according to the first aspect and a diffusion plate 120 arranged above the light emitting device 10.

The embodiments of the present application use the light emitting device 10 according to the first aspect as a backlight source. The light-transmissive resin 140 is provided on the light emitter 130 in the light emitting device 10, and a concave surface 142 is provided on the exit surface 141 of the light-transmissive resin 140, which is advantageous to expand the divergence angle of light from each light emitter 130, increase the spacing between adjacent light emitters 130, thereby reducing the number of light emitters 130 while ensuring the lightweight and the thinness and thereby saving energy consumption of the backlight module 1.

In some embodiments of the present application, the distance between the diffusion plate 120 and the substrate 100 is 3 mm to 10 mm. The distance between the diffusion plate 120 and the substrate 100 is the light mixing distance P. When the distance is less than 3 mm, the display panel may have alternating light and dark portions and uneven color. When the distance is greater than 10 mm, it is unfavorable for the backlight module 1 to be lighter in weight and thinner. Therefore, the embodiment of the present application is conducive to improving the lightweight and the thinness of the backlight module 1 while ensuring the display effect of the display panel.

In some embodiments of the present application, the distance between adjacent light emitters is 20 mm or more, which is advantageous to reduce the number of light emitters 130 and save energy consumption while ensuring the display effect of the display panel.

Specifically, embodiments and comparative examples are used to more specifically explain the above embodiments. Table 1 shows the comparison results of the light mixing distance P and the distance between adjacent light emitters in the conducted comparative example and the embodiments. In the comparative example, a layer of light-transmissive resin 111 is potted on the LED 110 in the backlight module, and the diameter of the light-transmissive resin 111 on the substrate 100 is 2.8 mm. In the embodiment of the present application, the light-transmissive resin 140 is provided on the light emitter 130 (LED 110), the concave surface 142 is also provided on the exit surface 141 of the light-transmissive resin 140, the diameter H of the orthographic projection of the light-transmissive resin 140 on the substrate 100 is 10 mm, and the height L is 2.52 mm.

Table 1 shows the comparison results of the light mixing distance P and the distance between adjacent LEDs in the comparative example and the embodiments.

| | light mixing | width at | spacing between |
|---|---|---|---|
| | distance | half height | adjacent LEDs |
| | P[mm] | [mm] | [mm] |
| comparative | 3 | 14.5 | 11 |
| example | | | |
| embodiment | 3 | 29.8 | 22 |
| comparative | 5 | 16.5 | 12 |
| example | | | |
| embodiment | 5 | 34 | 25 |
| comparative | 10 | 24 | 18 |
| example | | | |
| embodiment | 10 | 42 | 31 |

Table 1 shows the conditions that the light mixing distance P and the spacing between adjacent LEDs in the embodiment and the comparative example should meet when the display effect is guaranteed.

As can be seen from table 1, when the light mixing distances P are all 3 mm, the spacing between adjacent LEDs in the comparative example is 11 mm; and the spacing between adjacent LEDs in the embodiment of the present application can reach 22 mm. When the light mixing distances P are all the spacing between adjacent LEDs in the comparative example is 18 mm; and the spacing between adjacent LEDs in the embodiment of the present application can reach 31 mm. Therefore, using the light emitting device 10 according to the first aspect as the backlight in the embodiment of the present application is beneficial to reducing the number of light emitters 130 and reducing the energy consumption of the backlight module 1 while ensuring the lightweight and the thinness of the backlight module 1.

In a third aspect, the present application provides a display panel comprising the backlight module according to the second aspect.

The display panel in the embodiment of the present application comprises the backlight module 1 according to the second aspect. The backlight module 1 comprises the light emitting device 10 according to the first aspect. Wherein, the resin 140 is provided on the light emitter 130, and a concave surface 142 is provided on the exit surface 141 of the resin 140, which is advantageous to expand the divergence angle of light from each light emitter 130, increase the spacing between adjacent light emitters 130, thereby reducing the number of light emitters 130 while ensuring the lightweight and the thinness of the display panel and thereby saving energy consumption of the display panel.

It should be noted that the relationship terms herein such as “first”, “second”, and the like are only used for distinguishing one entity or operation from another entity or operation, but do not necessarily require or imply that there is any actual relationship or order between these entities or operations. Moreover, the terms “include”, “comprise” or any other variants thereof are intended to cover non-exclusive inclusions, so that processes, methods, articles or devices comprising a series of elements comprise not only those elements listed but also those not specifically listed or the elements intrinsic to these processes, methods, articles, or devices. Without further limitations, elements defined by the sentences “comprise(s) a” or “comprise(s) an” do not exclude that there are other identical elements in the processes, methods, articles, or devices which comprise these elements.

All the embodiments are described in corresponding ways, same or similar parts in each of the embodiments may be referred to one another, and the parts emphasized are differences from other embodiments. Especially for embodiments of a system, since they are similar to embodiments of a method, the description thereof is relatively simple; the similar parts could refer to the parts in the description of embodiments of the method.

The embodiments described above are merely preferred embodiments of the present application, and not intended to limit the scope of the present application. Any modifications, equivalents, improvements or the like within the spirit and principle of the application should be comprised in the scope of the application.

1. A light emitting device, comprising:
a substrate;
a plurality of light emitters mounted on the substrate and having centers and edges when viewed from above in a direction perpendicular to the substrate; and
a light-transmissive resin on each light emitter of the light emitters, wherein the resin is in close contact with the light emitter and a part of the substrate, and a surface of the resin away from the light emitter and the substrate forms an exit surface, wherein a center of the light emitter and a center of the exit surface are located in a first optical axis, and a region of the exit surface near the first optical axis is recessed toward the light emitter to form a concave surface, which is configured to totally reflect part of light emitted from the center of the light emitter and transmit part of light emitted from an edge of the light emitter;
wherein, the first optical axis is perpendicular to the substrate, and a line connecting the center of the light emitter and any point in the exit surface forms a first angle with the first optical axis;
light having the first angle that is greater than 0 degree and less than or equal to 40 degrees, among the light emitted from the center of the light emitter, is totally reflected by the concave surface;
wherein, the first optical axis is perpendicular to the substrate, and a line connecting the edge of the light emitter and any point in the exit surface forms a second angle with the first optical axis;
light having the second angle in a range of 0 to 10 degrees, among the light emitted from the edge of the light emitter, is transmitted through the concave surface.

2. The light emitting device according to claim 1, wherein, an orthographic projection of the resin on the substrate is circular;
the orthographic projection has a diameter of 8 mm to 10 mm.

3. The light emitting device according to claim 2, wherein, when the diameter of the orthographic projection is 8 mm, a height of the resin in a direction perpendicular to the substrate is 2 mm;
when the diameter of the orthographic projection is 10 mm, the height of the resin in the direction perpendicular to the substrate is 2.52 mm.

4. The light emitting device according to claim 1, wherein, phosphors or light-transmissive particles are provided in the resin.

5. A backlight module, comprising the light emitting device according to claim 1 and a diffusion plate arranged above the light emitting device.

6. The backlight module according to claim 5, wherein, a distance between the diffusion plate and the substrate is 3 mm to 10 mm.

7. The backlight module according to claim 5, wherein, a distance between adjacent light emitters is 20 mm or more.

8. A display panel, comprising the backlight module according to claim 5.
